(19) United States
(12) Patent Application Publication
(10) Pub. No.: US 2013/0240892 A1
(43) Pub. Date: Sep. 19, 2013

(54) METHOD FOR CONVERTING SEMICONDUCTOR LAYERS

(71) Applicants: Patrik Stenner, Hanau (DE); Matthias Patz, Bottrop (DE); Michael Coelle, Schwanstetten (DE); Stephan Wieber, Karlsruhe (DE)

(72) Inventors: Patrik Stenner, Hanau (DE); Matthias Patz, Bottrop (DE); Michael Coelle, Schwanstetten (DE); Stephan Wieber, Karlsruhe (DE)

(73) Assignee: EVONIK DEGUSSA GmbH, Essen (DE)

(21) Appl. No.: 13/885,316

(22) PCT Filed: Nov. 10, 2011
(86) PCT No.: PCT/EP11/69854

§ 371 Date: May 14, 2013

(30) Foreign Application Priority Data
Dec. 3, 2010 (DE) 10 2010 062 386.5

(51) Int. Cl. H01L 21/02; H01L 29/04; B23K 10/00

(52) U.S. Cl. CPC H01L 21/02027; B23K 10/00; H01L 29/04
USPC 257/75; 219/121.36; 438/798

(57) ABSTRACT

The present invention relates to a process for conversion of semiconductor layers, especially for conversion of amorphous to crystalline silicon layers, in which the conversion is effected by treating the semiconductor layer with a plasma which is generated by a plasma source equipped with a plasma nozzle (1). The present invention further relates to semiconductor layers produced by the process, to electronic and optoelectronic products comprising such semiconductor layers, and to a plasma source for performance of the process according to the invention.

The present invention relates to a process for conversion of semiconductor layers, especially for conversion of amorphous to crystalline silicon layers, to semiconductor layers produced in such a way, to electronic and optoelectronic products comprising such semiconductor layers and to a plasma source.

Depending on the process, the production of silicon layers at first gives rise to amorphous silicon. However, amorphous silicon when used later in the thin-film solar cell achieves only an efficiency of about 7%. Therefore, amorphous silicon is conventionally converted beforehand to crystalline silicon.

The conversion of semiconductor layers can be effected by supplying energy, for example by thermal treatment, by irradiation, for example with laser or infrared radiation, or by plasma treatment of the semiconductor layer.

Publication CN 101724901 describes a process for producing polycrystalline silicon layers, in which a multilayer silicon system is heat treated in an oven at 450° C. to 550° C. and 0.2 Torr to 0.8 Torr, and a hydrogen plasma is generated by addition of hydrogen.

Publication CN 101609796 describes a process for producing thin-film solar cells, in which a layer of amorphous silicon is heat treated under a hydrogen pressure of 100 atm to 800 atm.

The publication “Low-temperature crystallization of amorphous silicon by atmospheric-pressure plasma treatment”, AN 2006:1199072, Japanese Journal of Applied Physics, Part 1, describes the conversion of amorphous silicon by a plasma source having a cylindrical rotary electrode. The conversion is effected by evacuating the reaction chamber in which the layer to be treated is disposed, and then filling it with a hydrogen-helium or hydrogen-argon process gas until atmospheric pressure is attained, an atmospheric pressure plasma being generated by applying a high-frequency voltage with a frequency of 150 MHz between the rotary electrode and the substrate.

U.S. Pat. No. 6,130,397 B1 describes a process, which is very complex in apparatus terms, for treatment of thin layers with a plasma produced by inductive coupling. However, the process described therein works with a plasma which has very high temperatures (>5000 K) and as a result cannot be used for all conversion processes, since correspondingly high temperatures of the plasma can lead to inhomogeneous conversion.

The present invention thus provides a process for conversion of amorphous to crystalline semiconductor layers, which avoids the disadvantages described above, and in which the conversion is effected by treating the semiconductor layer with a plasma which is generated by a plasma source equipped with a plasma nozzle (1), and in which the semiconductor layer is heated to a temperature between ≧150° C. and ≦500° C.

A semiconductor layer may be understood to mean especially a layer which comprises or consists of at least one element semiconductor, preferably selected from the group consisting of Si, Ge, α-Sn, C, B, Se, Te and mixtures thereof, and/or at least one compound semiconductor, especially selected from the group consisting of IV-IV semiconductors such as SiGe, SiC, III-V semiconductors such as GaAs, GaSb, GaP, InAs, InSb, InP, InN, GaN, AlN, AlGaAs, InGaN, oxidic semiconductors such as InSnO, InO, ZnO, II-VI semiconductors such as ZnS, ZnSe, ZnTe, III-VI semiconductors such as GaS, GaSe, GaTe, InS, InSe, InTe, I-III-VI semiconductors such as CuInSe2, CuInGaSe2, CuInS2, CuInGaS2, and mixtures thereof.

The conversion of an amorphous to a crystalline material may be understood in the context of the present invention to mean especially the transformation of an amorphous to a crystalline material. Completion of conversion is measurable, for example, in the case of solar cells by an increase in light-induced charge transfer relative to the time before conversion. In general, the conversion of a material can be checked by Raman spectroscopy through a band shift (in the case of silicon through a shift in the characteristic band at 468 cm⁻¹).

More particularly, the semiconductor layer may be a silicon layer. A silicon layer may be either an essentially pure silicon layer or a silicon-containing layer, for example a silicon-based layer additionally comprising dopants, or a silicon-containing compound semiconductor layer. More particularly, the process can convert an amorphous silicon layer to a crystalline silicon layer.

In one embodiment, the conversion is effected by treating the semiconductor layer with a plasma which is generated by a plasma source equipped with a plasma nozzle. Such plasma sources are indirect plasma sources. An indirect plasma source may be understood to mean a plasma source in which the plasma is generated outside the reaction zone containing the semiconductor layer. The plasma generated can be blown onto the semiconductor layer to be treated, especially with formation of a kind of “plasma flare”.

A plasma generated with a plasma nozzle plasma source has the advantage that the actual plasma formation is not affected by the substrate. For instance, it is advantageously possible to achieve high process reliability. Correspondingly produced plasmas additionally have the advantage that they are potential-free, and therefore damage to the surface as a result of discharge can be avoided. In addition, introduction of extraneous metal onto the surface can be avoided, since the substrate does not serve as an opposite pole.

The plasma source may especially have an inner electrode disposed in the cavity of the plasma nozzle and electrically insulated from the plasma nozzle. By feeding the process gas into the cavity of the plasma nozzle and applying an electrical potential difference to the inner electrode and the plasma nozzle, it is possible in such a plasma source to generate a plasma between the inner electrode and the plasma nozzle by means of self-sustaining gas discharge. The plasma source may especially be a high-voltage gas discharge plasma source or a light arc plasma source.

The plasma can especially be generated by means of a light arc or by means of a high-voltage gas discharge, for example with a buildup voltage of ≧8 kV to ≦30 kV. More particularly, the plasma can be generated by a high-voltage gas discharge plasma source or a light arc plasma source. For example, the plasma can be generated by a pulsed voltage, for example a rectangular voltage, or an AC voltage. For example, the plasma can be generated by a rectangular voltage of ≧15 kHz to ≦5.25 kHz and/or ≧0 V to ≦400 V, for example ≦260 to ≦300 V, for example 280 V, and/or with a current of ≧2.2 A to ≦3.2 A and/or a plasma cycle of ≧50% to ≦100%. More particularly, the plasma can be generated by a high-pressure gas discharge at currents of <45 A, for example ≧0.1 A to ≦44 A, for example from ≧1.5 A to ≦3 A, DC. A high-pressure gas discharge may be understood to mean especially a gas discharge at pressures of ≧0.5 bar to ≦8 bar, for example of ≧1 bar to ≦5 bar. Before being fed in, the process gas can be mixed from different gases, for example noble gas(es), especially argon, and/or nitrogen and/or hydrogen. According to the selection of the gases and further parameters, it is thus possible to obtain plasma temperatures of up to 3000 K. The treatment width of the plasma nozzle may be, for example, from ≧0.25 mm to ≦20 mm, for example from ≧1 mm to ≧5 mm. Plasma sources which are equipped with a plasma nozzle and are suitable for performance of the process (plasma nozzle plasma sources) are sold, for example, under the Plasmajet commercial product name by Plasmatreat GmbH, Germany, or under the Plasmabeam commercial product name by Diener GmbH, Germany.

In a further embodiment, the plasma is generated by a voltage with a frequency of <30 kHz, for example from ≧15 kHz to ≦25 kHz, for example of ˜20 kHz. Due to the low frequencies, the energy input is advantageously particularly low. The low energy input in turn has the advantage that damage to the surface of the semiconductor layer can be avoided.

In a further embodiment, the conversion is effected at atmospheric pressure. More particularly, the plasma source may be an atmospheric pressure plasma source. Thus, it is advantageously possible to dispense with a costly low-pressure or high-pressure process. In addition, compared to low-pressure processes or vacuum processes, it is possible to reduce the residence time since a higher energy density can be achieved at atmospheric pressure as a result of the higher molecule density.

Before being fed in, the process gas can be mixed from different gases, for example noble gas(es), especially argon, and/or nitrogen and/or hydrogen. The different gases can especially be mixed in an adjustable ratio relative to one another.

In a further embodiment, the plasma is obtained from a process gas which comprises a noble gas or noble gas mixture, especially argon, and/or nitrogen.

It has been found that semiconductor layers can be converted by treatment with a plasma generated from a noble gas-containing, especially argon-containing, and/or nitrogen-containing process gas. More particularly, treatment with a plasma generated from a noble gas-containing, especially argon-containing, and/or nitrogen-containing process gas can convert amorphous silicon layers to crystalline silicon layers. The use of a nitrogen-containing process gas or the use of nitrogen instead of noble gases in the process gas has the advantage that the process costs can be lowered significantly, since nitrogen is less expensive than noble gases such as argon or helium.

It has been found that pure nitrogen can be used as the process gas in order to obtain a plasma whose plasma temperature is suitable for conversion of semiconductor layers. Depending on the semiconductor layer to be treated or the substrate thereof, it may, however, be advisable to set the plasma temperature at a higher or lower level. More particularly, a higher plasma temperature can be established in the case of semiconductor layers on substrates with a high thermal conductivity, for example metallic substrates, and a lower plasma temperature in the case of semiconductor layers on substrates with low thermal conductivity, for example glass substrates such as EAGLE glass substrates.

In this context, it has been found that the plasma temperature of a plasma generated from a nitrogen-containing process gas can firstly be lowered by increasing the process gas pressure or the process gas velocity and, conversely, increased by reducing the process gas pressure or the process gas velocity.

Secondly, it has been found that the plasma temperature of a plasma generated from a nitrogen-containing process gas can be lowered by adding noble gases, such as argon, or by increasing the noble gas content and, conversely, increased by lowering the noble gas content.

In addition, it has been found that the plasma temperature of a plasma generated from a noble gas-containing process gas can be increased by adding nitrogen and/or hydrogen or by increasing the nitrogen content and/or hydrogen content, and conversely lowered by lowering the nitrogen content and/or hydrogen content.

The process gas pressure and the process gas composition can be adjusted, for example, so as to result in plasma temperatures of ≧750° C.

The temperature at which the semiconductor layer is treated can also be adjusted by further process parameters.

The treatment temperature can be reduced, for example, by increasing the distance between the site of plasma generation and the semiconductor layer to be treated, and, conversely, increased by reducing the distance between the site of plasma generation and the semiconductor layer to be treated.

In addition, the treatment temperature can be increased by prolonging the treatment time with the plasma, and conversely reduced by shortening the treatment time with the plasma. In the course of the process, the plasma can be moved over the semiconductor layer, especially parallel to the semiconductor layer. This can be accomplished, for example, by an X/Y plotter. This allows the treatment temperature to be increased by slowing the rate with which the plasma is moved over the semiconductor layer, and reduced by increasing the rate with which the plasma is moved over the semiconductor layer.

In a further embodiment, the process gas further comprises hydrogen. As already explained, it is thus advantageously possible to increase the plasma temperature if required. In addition, the semiconductor layer can thus advantageously be converted simultaneously, and the dangling bonds which possibly form on the surface and in the interior of the semiconductor layer in the course of conversion can be satisfied with hydrogen or passivated. Therefore, the process in this embodiment can be referred to especially as a process for conversion and for hydrogen passivation of semiconductor layers. The simultaneous conversion and hydrogen passivation can advantageously reduce the number of process steps and avoid different process steps, and hence lower the overall production costs for semiconductor layers. Hydrogen passivation is measurable, for example, for solar cells by an increase in light-induced charge transfer relative to the time before passivation. In general, the hydrogen passivation can be checked by IR spectroscopy through the change in the bands of the particular semiconductor (for silicon layers: through the change in the characteristic band at 2000 cm⁻¹). Advantageously, a small amount of hydrogen is sufficient for passivation, which has an advantageous effect on the process costs.

In principle, the process gas may comprise ≧0% by volume to ≦100% by volume, especially ≧50% by volume or ≧90% by volume or ≧95% by volume to ≦100% by volume or ≦99.9% by volume or ≦99.5% by volume or ≦95% by volume or ≦90% by volume, for example ≧95% by volume to ≦99.5% by volume, of noble gas(es), especially argon, and/or ≧0% by volume to ≦100% by volume, especially ≧50% by volume or ≧90% by volume or ≧95% by volume to ≦100% by volume or ≦99.9% by volume or ≦99.5% by volume or ≦95% by volume or ≦90% by volume, for example ≧95% by volume to ≦99.5% by volume, of nitrogen and/or ≧0% by volume to ≦10% by volume, especially ≧0% by volume or ≧0.1% by volume or ≧0.5% by volume to ≦10% by volume or ≦5% by volume, of hydrogen, especially where the sum of the percentages by volume of nitrogen and/or noble gas(es) and/or hydrogen adds up to a total of 100 percent by volume.

It is possible either that the process gas contains noble gas but not nitrogen, or that the process gas contains nitrogen but not noble gas. In addition, it is possible that the total content of noble gas(es) and nitrogen in the process gas is ≧0% by volume to ≦100% by volume, especially ≧50% by volume or ≧90% by volume or ≧95% by volume to ≦100% by volume or ≦99.9% by volume or ≦99.5% by volume or ≦95% by volume or ≦90% by volume, for example ≧95% by volume to ≦99.5% by volume. For example, the process gas may comprise ≧0% by volume to ≦100% by volume, especially ≧50% by volume to ≦90% by volume, of nitrogen and/or ≧0% by volume to ≦50% by volume or ≦40% by volume, of noble gas(es), especially argon. In addition, the process gas may comprise ≧0% by volume or ≧0.1% by volume to ≦10% by volume, for example ≧0.5% by volume to ≦5% by volume, of hydrogen. The sum of the percentages by volume of nitrogen, noble gas(es) and/or hydrogen preferably adds up to a total of 100 percent by volume.

More particularly, the process gas may consist of >0% by volume to ≦100% by volume, especially ≧50% by volume or ≧90% by volume or ≧95% by volume to ≦100% by volume or ≦99.9% by volume or ≦99.5% by volume or ≦95% by volume or ≦90% by volume, for example ≧90% by volume or ≧95% by volume to ≦99.9% by volume or ≦99.5% by volume, of noble gas(es), especially argon, and/or nitrogen, for example of ≧50% by volume to ≦90% by volume of nitrogen and/or ≧0% by volume to ≦50% by volume, especially ≧5% by volume to ≦40% by volume, of noble gas(es), and ≧0% by volume to ≦10% by volume, especially ≧0.5% by volume to ≦5% by volume, of hydrogen, especially where the sum of the percentages by volume of nitrogen, noble gas(es), especially argon, and hydrogen adds up to a total of 100 percent by volume. A process gas with such a composition has been found to be especially advantageous for conversion of semiconductor layer.

In a further embodiment, the process gas comprises ≧90% by volume to ≦99.9% by volume, for example ≧95% by volume to ≦99.5% by volume, of noble gas(es), especially argon, and/or nitrogen (i.e. of noble gas(es) or of nitrogen or of noble gas(es) and nitrogen together), and ≧0.1% by volume to ≦10% by volume, for example ≧0.5% by volume to ≦5% by volume, of hydrogen, especially where the sum of the percentages by volume of nitrogen, noble gas(es) and hydrogen adds up to a total of 100 percent by volume.

In a further embodiment, the treatment temperature is adjusted by adjusting the composition of the process gas. For example, the plasma temperature and hence also the treatment temperature can be lowered by adding noble gases such as argon, or by increasing the noble gas content, and conversely increased by lowering the noble gas content. By replacing a noble gas content with a hydrogen content, the plasma temperature and hence also the treatment temperature can be increased, and conversely lowered by replacing a hydrogen and/or nitrogen content with a noble gas content. More particularly, the proportions of nitrogen, noble gas, especially argon, and hydrogen can be varied within the ranges described above to adjust the plasma and treatment temperature.

In a further embodiment, the treatment temperature is adjusted by adjusting the process gas pressure or the process gas velocity. For example, the process gas pressure can be varied within a range from ≧0.5 bar to ≦8 bar, for example ≧1 bar to ≦5 bar. The plasma temperature and hence also the treatment temperature falls with rising process gas pressure or rising process gas velocity, and rises with falling process gas pressure or falling process gas velocity.

In a further embodiment, the treatment temperature is adjusted by adjusting the distance between the site of plasma generation and the semiconductor layer to be treated, for example between a plasma nozzle and the semiconductor layer. The treatment temperature falls when the distance is increased and rises when the distance is reduced. For example, the distance between a plasma nozzle and the semiconductor layer to be treated can be adjusted within a range from 50 μm to 50 mm, preferably 1 mm to 30 mm, especially preferably 3 mm to 10 mm.

To achieve particularly good conversion, the plasma jet leaving the nozzle is preferably directed at an angle of 5 to 90°, preferably 80 to 90°, more preferably 85 to 90° (in the latter case: essentially at right angles to the substrate surface for planar substrates) onto the semiconductor layer present on the substrate.

Suitable nozzles for the light arc plasma source are point nozzles, fan nozzles or rotary nozzles, preference being given to using point nozzles which have the advantage that a higher point energy density is achieved.

In a further embodiment, the treatment temperature is adjusted by adjusting the treatment time, especially the treatment rate with which the plasma is moved over the semiconductor layer. The treatment temperature falls in the event of shortening of the treatment time or in the event of an increase in the treatment rate with which the plasma is moved over the semiconductor layer, and increases in the event of prolonging of the treatment time or in the event of a decrease in the treatment rate with which the plasma is moved over the semiconductor layer. Particularly good conversion is achieved, especially for the abovementioned distances of the nozzle from the semiconductor layer to be treated, when the treatment rate, determined as the treated length of the semiconductor layer per unit time, is 0.1 to 500 mm/s with a treatment width of 1 to 15 mm. According to the semiconductor surface to be treated, heat treatment also accelerates the conversion. To increase the treatment rate, several plasma nozzles can be connected in series.

In a steady-state process regime, the treatment width of the plasma nozzle to achieve good conversion is preferably 0.25 to 20 mm, more preferably 1 to 5 mm.

The heat treatment of the semiconductor layer at a temperature between ≧150° C. and ≦500° C., for example between ≧200° C. and ≦400° C., allows the conversion to be performed homogeneously, and the conversion and optionally passivation of the semiconductor layer to be accelerated. Temperatures of ≧600° C. are disadvantageous, however, since they can lead to a melt of the substrates. In principle, the heat treatment can be effected by the use of ovens, heated rollers, hotplates, infrared or microwave radiation or the like. However, due to the low complexity which then results, particular preference is given to performing the heat treatment with a hotplate or with heated rollers in a roll-to-roll process.

The process also enables simultaneous treatment of several semiconductor layers one on top of another. For example, it is possible by the process to convert and optionally passivate semiconductor layers of different degrees of doping (p/n doping) or undoped semiconductor layers. The process has good suitability, for example, for conversion and optional passivation of several layers one on top of another, the layer thicknesses of each of which are within a range between 10 nm and 3 μm, preference being given to layer thicknesses between 10 nm and 60 nm, 200 nm and 300 nm, and 1 μm and 2 μm.

With regard to further features and advantages of the process according to the invention, reference is hereby made here explicitly to the explanations in connection with the inventive plasma source and the description of the figures.

The present invention further provides a semiconductor layer which has been produced by a process according to the invention.

With regard to further features and advantages of the inventive semiconductor layer, reference is hereby made explicitly to the explanations in connection with the process according to the invention, the inventive plasma source and the description of the figures.

The present invention further provides an electronic or optoelectronic product, for example photovoltaic device, transistor, liquid-crystal display, especially solar cell, which comprises an inventive semiconductor layer.

With regard to further features and advantages of the inventive product, reference is hereby made explicitly to the explanations in connection with the process according to the invention, the inventive plasma source and the description of the figures.

The present invention further provides a plasma source which comprises a plasma nozzle, an inner electrode arranged within the cavity of the plasma nozzle and electrically insulated from the plasma nozzle, and a gas and voltage supply device for feeding a process gas into the cavity of the plasma nozzle and for applying an electrical potential difference, especially a high voltage, to the inner electrode and the plasma nozzle, in order to generate a plasma between the inner electrode and the plasma nozzle by means of self-sustaining gas discharge or a light arc. The gas and voltage supply device comprises at least two, for example at least three, gas connections for feeding in different gas species, especially noble gas(es), especially argon, and/or nitrogen and/or hydrogen, and a gas mixing unit for mixing the process gas from the different gas species.

Such a plasma source is advantageously suitable for performance of the process according to the invention. For instance, the plasma can be generated by means of a light arc or by means of a high-voltage gas discharge, for example a buildup voltage of ≧8 kV to ≦30 kV. Therefore, the plasma source can also be referred to as a light arc plasma source or high-voltage gas discharge plasma source. In addition, such a plasma source is advantageously an indirect plasma source. Advantageously, the plasma source can additionally be operated at atmospheric pressure.

The gas mixing unit is preferably designed to mix the different gas species in an adjustable ratio relative to one another. A plasma source of such a configuration has been found to be particularly advantageous for performance of the process according to the invention. The gas mixing unit can either be integrated into the gas and voltage supply device or connected to the gas and voltage supply device.

The plasma source may especially be designed to generate the plasma by means of a pulsed voltage, for example a rectangular voltage, or an AC voltage. For example, the plasma source may be designed to generate the plasma by means of a rectangular voltage of ≧15 kHz to ≦25 kHz. This has been found to be advantageous for performance of the process according to the invention.

The plasma source is preferably designed to generate the plasma by means of a voltage with a frequency of <30 kHz, for example of ≧15 kHz to ≦25 kHz, for example ˜20 kHz. This has been found to be particularly advantageous for performance of the process according to the invention.

With regard to further features and advantages of the inventive plasma source, reference is hereby made explicitly to the explanations in connection with the process according to the invention and the description of the figures.

### DRAWINGS AND EXAMPLES

Further advantages and advantageous configurations of the subject-matter of the invention are illustrated by the drawings and examples and explained in the description which follows. It should be noted that the drawings and examples are merely of descriptive character and are not intended to restrict the invention in any way. The figures show:

FIG. 1 a schematic cross section through one embodiment of an inventive plasma source with a plasma nozzle;

FIG. 2 a schematic cross section through another embodiment of an inventive plasma source with a plasma nozzle;

FIG. 3 Raman spectra of a silicon layer before and after performance of a first embodiment of the process according to the invention;

FIG. 4 Raman spectra of a silicon layer before and after performance of a second embodiment of the process according to the invention;

FIG. 5a Raman spectra of a silicon layer before and after performance of a third embodiment of the process according to the invention;

FIG. 5b IR spectra of the silicon layer from FIG. 5a before and after performance of the third embodiment of the process according to the invention; and

FIG. 6 Raman spectra of a silicon layer after performance of a fourth embodiment of the process according to the invention.

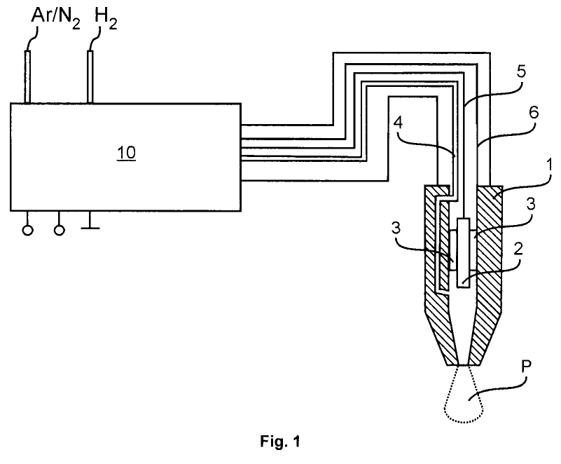

FIG. 1 shows one embodiment of an inventive atmospheric pressure plasma source which is equipped with a plasma nozzle and is suitable for performance of the process according to the invention. FIG. 1 shows that the plasma source comprises a plasma nozzle 1 and an inner electrode 2 arranged within the cavity of the plasma nozzle 1 and separated electrically by insulators 3 from the plasma nozzle 1. A gas can be introduced into the cavity of the plasma nozzle 1 from a gas and voltage supply device 10 via a gas line 4. The inner electrode 2 is electrically connected to the gas and voltage supply device 10 via an electrical wire 5. The plasma nozzle 1 is connected electrically to the gas and voltage supply device 10 via a further electrical wire 6 and serves as a potential-free electrode.

FIG. 1 illustrates that the gas and voltage supply device 10 has two gas connections Ar/N2, H2 for feeding in different gas species, such as nitrogen and/or noble gas(es), especially argon, and/or hydrogen. More particularly, FIG. 1 shows that the gas and voltage supply device 10 has a noble gas and/or nitrogen connection, especially argon connection, Ar/N2 and a hydrogen connection H2. In addition, the gas and voltage supply device 10 has a gas mixing unit (not shown) for mixing the process gas from the different gas species. The gas mixing unit is preferably designed to mix the different gas species, especially noble gas(es), especially argon, and/or nitrogen and/or hydrogen, in an adjustable ratio relative to one another.

In addition, the gas and voltage supply device 10 has a power connection for connection of the gas and voltage supply device 10 to the power grid. In addition, the gas and voltage supply device 10 is designed to generate a (high) voltage and apply it to the inner electrode 2 and the plasma nozzle 1, in order to generate a plasma between the inner electrode 2 and the plasma nozzle 1 by means of self-sustaining gas discharge.

By applying a potential difference between the inner electrode 2 and the plasma nozzle, and supplying the plasma nozzle 1 with the process gas, it is possible to generate an atmospheric pressure plasma P within the plasma nozzle 1 with formation of a light arc or a self-sustaining gas discharge, especially a high-voltage gas discharge, and to blow it out onto the substrate to be treated through the plasma nozzle 1.

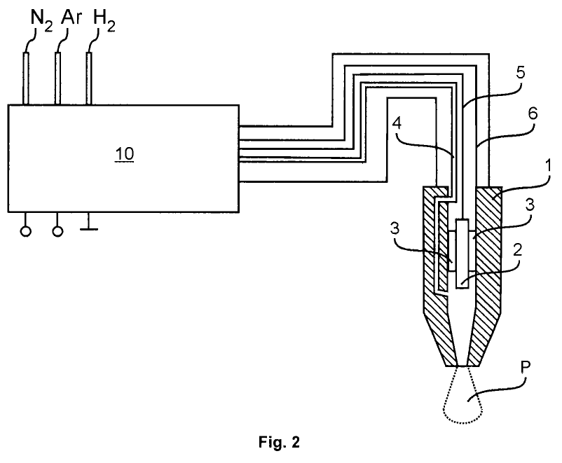

The embodiment shown in FIG. 2 differs essentially from the embodiment shown in FIG. 1 in that the gas and voltage supply device 10 has three gas connections N2, Ar, H2 for feeding in different gas species, such as nitrogen and/or noble gas(es), especially argon, and/or hydrogen. More particularly, FIG. 1 shows that the gas and voltage supply device 10 has a nitrogen connection N2, a noble gas connection, especially argon connection, Ar, and a hydrogen connection, H2. In this embodiment too, the gas and voltage supply device 10 additionally has a gas mixing unit (not shown) for mixing the process gas from the different gas species. The gas mixing unit is preferably designed to mix the different gas species, especially noble gas(es), especially argon, and/or nitrogen and/or hydrogen, in an adjustable ratio relative to one another.

### EXAMPLES

By means of a spin-coating process, several hydridosilane-coated substrates were produced. The hydrosilane-coated substrates were placed on a ceramic hotplate, and above them was positioned a Plasmajet (FG3002), equipped with a round nozzle, from Plasmatreat GmbH at a defined distance. Subsequently, the coated substrates were treated with a plasma generated from different process gases under atmospheric pressure. The Plasmajet had a power of about 800 W, a frequency of 21 kHz, a voltage of 280 V and a current of 2.3 A. In Examples 2 and 3, the process gas was mixed from the different gas species in a gas mixing unit and supplied in mixed form to the Plasmajet.

The process conditions of four different plasma treatments are compiled in Table 1 below:

| | Example 1 | | Example 2 | | Example 3 | | Example 4 | |
|---|---|---|---|---|---|---|---|---|
| Substrate | SiO₂ wafer | | SiO₂ wafer | | SiO₂ wafer | | EAGLE glass | |
| Hotplate temperature | unheated | | unheated | | 400° | C. | unheated | |
| Process gas | 100% by vol. of N2 | | 60% by vol. of N2, | | 77.6% by vol. of N2, | | 100% by vol. of N2 | |
| | | | 40% by vol. of Ar | | 20% by vol. of Ar, | | | |
| | | | | | 2.4% by vol. of H2 | | | |
| Substrate-nozzle | 5 | mm | 4 | mm | 8 | mm | 8 | mm |
| distance | | | | | | | | |
| Residence time/line | <10 | s | <10 | s | 10 | mm/s | <10 | s |
| speed* | | | | | | | | |

*In Example 3, the Plasmajet was conducted over the silicon layer with an XY plotter.

In all examples, the silicon layers after the inventive treatment exhibited a blue-green colour visible to the naked eye, which can be evaluated as the first indication of successful conversion.

Before and/or after the plasma treatment, the silicon layers of Examples 1 to 4 were analysed by means of Raman spectroscopy. The silicon layer of Example 3 was additionally analysed by means of IR spectroscopy.

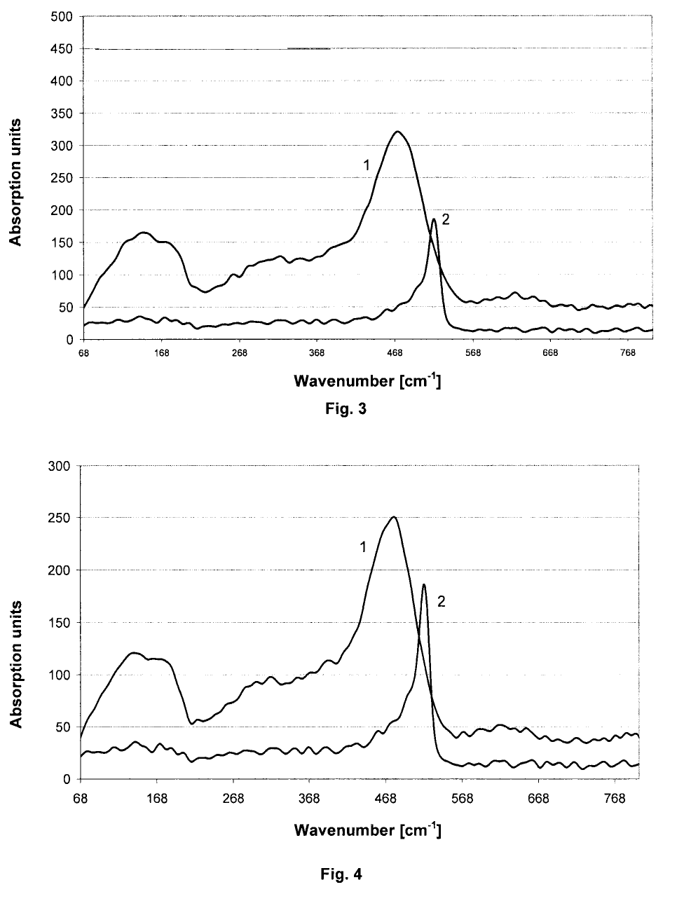

FIGS. 3, 4 and 5a each show a comparison of the Raman spectra of the silicon layers of Examples 1, 2 and 3 before (1) and after (2) the plasma treatment. The band shift from 470 cm⁻¹ to 520 cm⁻¹ shows that a conversion of amorphous to crystalline silicon has taken place in Examples 1, 2 and 3.

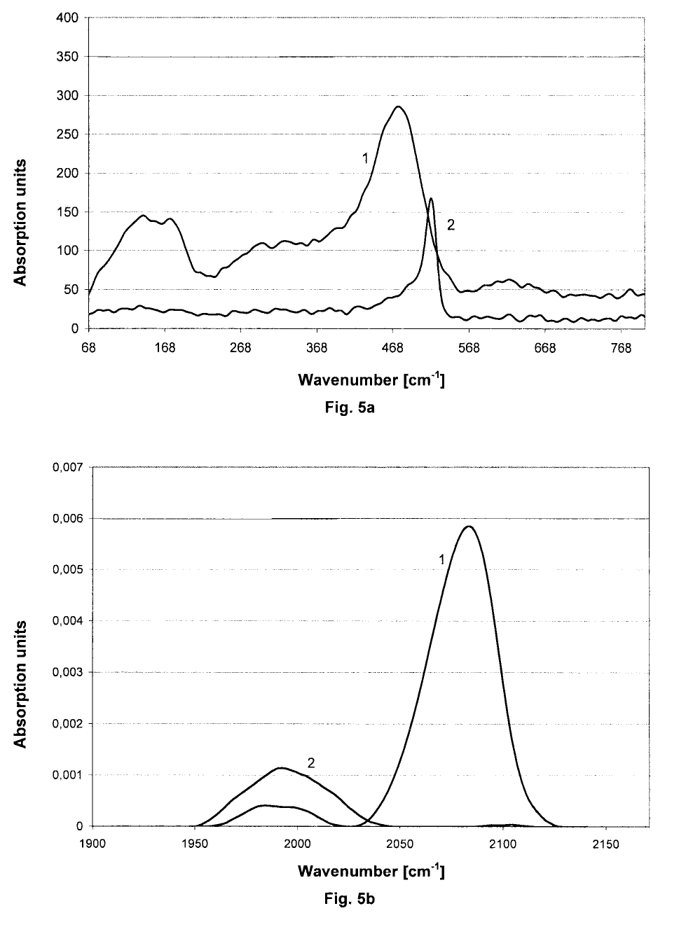

FIG. 5b shows a comparison of the IR spectra of the silicon layer of Example 3 before (1) and after (2) the plasma treatment. The rise in the peak at a wavenumber of 2000 cm⁻¹ shows that, in Example 3—in addition to the conversion of amorphous to crystalline silicon—a satisfaction of the dangling bonds with hydrogen (hydrogen passivation) has taken place.

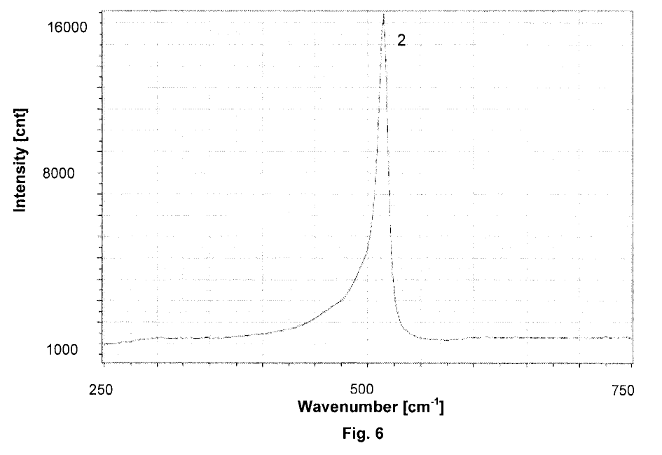

FIG. 6 shows the Raman spectrum of the silicon layer of Example 4 after (2) the plasma treatment. The band at 520 cm⁻¹ shows that a conversion of amorphous to crystalline silicon has taken place in Example 4 too.

1. A process for converting a semiconductor layer from an amorphous state thereof to a crystalline state thereof, the process comprising:
generating a plasma from a plasma source comprising a plasma nozzle; and
heat-treating the semiconductor layer with the plasma at a temperature between ≧150° C. and ≦500° C.

2. The process according to claim 1, wherein the generating is generating the plasma by applying a voltage having a frequency of <30 kHz.

3. The process according to claim 1, wherein the heat-treating is heat-treating at atmospheric pressure.

4. The process according to claim 1, wherein the generating is generating the plasma from a process gas comprising at least one noble gas, nitrogen, or both.

5. The process according to claim 4, wherein the process gas further comprises hydrogen.

6. The process according to claim 5, wherein the process gas comprises:
from 90% to 99.9% by volume of the at least one noble gas, the nitrogen, or both; and
from 0.1% to 10% by volume of the hydrogen.

7. The process according to claim 1, wherein the temperature in the heat-treating is established by adjusting:
a composition of the process gas;
a process gas pressure or a process gas velocity;
a distance between the plasma nozzle and the semiconductor layer;
a treatment time, or
a combination thereof.

8. A semiconductor layer produced by the process according to claim 1.

9. An electronic or optoelectronic product, comprising the semiconductor layer according to claim 8.

10. A plasma source, comprising:
a plasma nozzle;
an inner electrode; and
a gas and voltage supply device comprising at least two gas connections and a gas mixing unit;
wherein the inner electrode is arranged within a cavity of the plasma nozzle and is electrically insulated from the plasma nozzle, the gas and voltage supply device is suitable for feeding a process gas into the cavity and for applying an electrical potential difference to the inner electrode and the plasma nozzle to generate a plasma between the inner electrode and the plasma nozzle via a self-sustaining gas discharge, the at least two gas connections are suitable for feeding in different gas species, and the gas mixing unit is suitable for mixing the process gas comprising the different gas species.

11. The process according to claim 1, wherein the semiconductor layer is a silicon layer.

12. The process according to claim 4, wherein the process gas comprises argon, the nitrogen, or both.

13. The process according to claim 12, wherein the process gas further comprises hydrogen.

14. The process according to claim 6, wherein the process gas contains the at least one noble gas, the nitrogen, or both and the hydrogen.

15. The process according to claim 7, wherein the treatment time is a treatment rate in which the plasma is moved over the semiconductor layer.

16. The electronic or optoelectronic product of claim 9, wherein the electronic or optoelectronic product is a solar cell.

17. The plasma source according to claim 10, wherein the plasma source is an indirect plasma source.

18. The plasma source according to claim 10, wherein the gas and voltage supply device comprises at least three gas connections for feeding in different gas species.

19. The plasma source according to claim 10, wherein the gas mixing unit mixes the different gas species in an adjustable ratio relative to one another.
